(19) United States
(12) Patent Application Publication
(10) Pub. No.: US 2016/0289372 A1
(43) Pub. Date: Oct. 6, 2016

(54) POLYMERIZABLE COMPOSITION, RESIN SHAPED ARTICLE, COMPOSITE, AND LAMINATE

(71) Applicant: ZEON CORPORATION, Tokyo (JP)

(72) Inventor: Osamu Kawakami, Tokyo (JP)

(73) Assignee: ZEON CORPORATION, Tokyo (JP)

(21) Appl. No.: 14/777,551

(22) PCT Filed: Mar. 17, 2014
(86) PCT No.: PCT/JP2014/057077

§ 371 Date: Sep. 16, 2015

(30) Foreign Application Priority Data
Mar. 19, 2013 (JP) 2013-056283
Mar. 19, 2013 (JP) 2013-056285

(51) Int. Cl. C08G 61/08; B32B 15/04; B32B 15/20; H05K 1/09

(52) U.S. Cl. CPC C08G 61/08; H05K 1/09; B32B 15/04; B32B 15/20; C08G 2261/128; C08G 2261/3325; C08G 2261/418; C08G 2261/149; C08G 2261/1426; C08G 2261/148; C08G 2261/65; C08G 2261/62; B32B 2307/202; B32B 2457/08; B32B 2255/06; B32B 2255/26

(57) ABSTRACT

A polymerizable composition comprising a cycloolefin monomer (A), a metathesis polymerization catalyst (B), and a polymer (C) which has a triazine structure and a resin shaped article, composite, and laminate which are obtained using this are provided. According to the present invention, it is possible to provide a polymerizable composition which is useful for the manufacture of a laminate which has a low dielectric tangent in a high frequency region and is excellent in peel strength and a resin shaped article, composite, and laminate which are obtained using this.

### TECHNICAL FIELD

The present invention relates to a polymerizable composition, resin shaped article, composite, and laminate.

### BACKGROUND ART

In recent years, in information transmission, there has been rising demand for use of higher frequencies, high densities, etc. Higher precision, greater number of layers, and more miniaturized high performance circuit boards have been being developed. For circuit boards which are used for information transmission in the high frequency regions, materials with smaller transmission loss have been sought. As such materials, from the viewpoint of the lower dielectric tangent and thereby the ability to make the transmission loss smaller, a cycloolefin polymer obtained by polymerizing a cycloolefin monomer is coming under the spotlight.

For example, Patent Document 1 discloses a method of dipping a double-sided copper-clad board in an alcohol solution of a triazine compound to thereby obtain a double-sided copper clad board on the surfaces of which primer layers comprised of a triazine compound are formed and bonding and hot pressing shaped articles comprised of a cycloolefin polymer which is obtained by ring opening polymerization of a cycloolefin monomer on the primer layers of the double-sided copper clad board to thereby obtain a circuit board.

### PRIOR ART DOCUMENTS

### Patent Documents

Patent Document 1: Japanese Patent No. 3862009 (International Publication No. WO2003/024174)

### DISCLOSURE OF THE INVENTION

### Problem to be Solved by the Invention

The art of the above Patent Document 1 is art for improving the bondability (peel strength) between the shaped articles comprised of the cycloolefin polymer and the double-sided copper-clad board, that is, between the metal (copper) and the shaped articles, by providing the double-sided copper-clad board with primer layers comprised of a triazine compound. Due to this, improvement of the bondability between the shaped articles comprised of the cycloolefin polymer and the double-sided copper-clad board becomes possible. However, in the art of this Patent Document 1, to form primer layers comprised of a triazine compound, numerous steps such as a step of dipping the double-sided copper-clad board in an alcohol solution of the triazine compound, a step of removing the alcohol after dipping and a step of laminating the shaped articles comprised of the cycloolefin polymer and the double-sided copper-clad board on which the primer layers are formed, become necessary and there was the issue that the productivity was low. Furthermore, in the art of this Patent Document 1, the interaction between the cycloolefin polymer and the triazine compound which forms the primer layers was not necessarily sufficient. Therefore, the effect of improvement of the bondability by the primer layers was also limited. A sufficient bondability (peel strength) could not necessarily be realized.

The present invention has as its object the provision of a polymerizable composition and a resin shaped article which are useful for the manufacture of a laminate which has a low dielectric tangent in the high frequency region and is excellent in peel strength with metal, and the provision of a composite and laminate which utilize these.

### Means for Solving the Problems

The inventors engaged in intensive research for achieving the above object and as a result discovered that by using a polymerizable composition comprising, in addition to a cycloolefin monomer and metathesis polymerization catalyst, a polymer which has a triazine structure at its side chain, a laminate which has a low dielectric tangent in the high frequency region and is excellent in peel strength can be obtained and completed the present invention based on this discovery.

That is, according to the present invention, there are provided

[1] A polymerizable composition which comprises a cycloolefin monomer (A), a metathesis polymerization catalyst (B), and a polymer (C) which has a triazine structure,
[2] The polymerizable composition according to [1], wherein the polymer (C) which has a triazine structure is a triazine structure-containing polymer (C1) which is obtained by causing a compound represented by the following general formula (1A) or (1B) and a compound represented by the following general formula (2A) or (2B) to react by a condensation reaction.

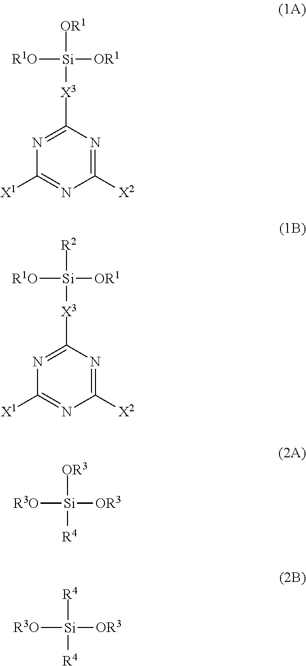

[where in the above general formulas (1A) and (1B), R¹ is a hydrogen atom or an alkyl group having 1 to 6 carbon atoms, R² is an alkyl group having 1 to 6 carbon atoms, alkenyl group having 2 to 6 carbon atoms, cycloalkyl group having 3 to 14 carbon atoms, cycloalkenyl group having 3 to 14 carbon atoms or aryl group having 6 to 12 carbon atoms which may have a substituent group, X¹ and X² respectively independently are a group represented by —H, —OR⁵, —SR⁶, or —NR⁷R⁸ (R⁵ to R⁸ respectively independently are a hydrogen atom, or an alkyl group having 1 to 12 carbon atoms or aryl group having 6 to 12 carbon atoms which may have a substituent group.), X³ is a chemical single bond or group represented by —R⁹—O—R¹⁰—, —R¹¹—S—R¹²—, or —R¹³—C(═O)—OR¹⁴— (R⁹ to R¹⁴ respectively independently are an alkylene group having 1 to 6 carbon atoms which may have a substituent group.),

where in the above general formulas (2A) and (2B), R³ is a hydrogen atom or alkyl group having 1 to 6 carbon atoms, R⁴ is an alkyl group having 1 to 6 carbon atoms, alkenyl group having 2 to 6 carbon atoms, cycloalkyl group having 3 to 14 carbon atoms, cycloalkenyl group having 3 to 14 carbon atoms or aryl group having 6 to 12 carbon atoms which may have a substituent group, and

the triazine structure-containing polymer may be obtained by a condensation reaction using two or more compounds having different structures as one or both of the compound represented by the above general formula (1A) or (1B) and the compound represented by the above general formula (2A) or (2B).],

[3] The polymerizable composition according to [1], wherein the polymer (C) which has a triazine structure is a triazine structure-containing polymer (C2) which has units represented by the following general formula (3) and units represented by the following general formula (4).

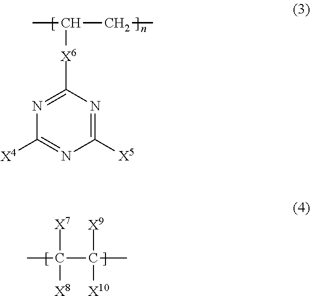

[where in the above general formula (3), X⁴ and X⁵ respectively independently are a group represented by —H, —OR¹⁵, —SR¹⁶, or —NR¹⁷R₁₈ (R¹⁵ to R¹⁸ respectively independently are a hydrogen atom or an alkyl group having 1 to 12 carbon atoms or aryl group having 6 to 12 carbon atoms which may have a substituent group), X⁶ is a chemical single bond or group represented by —R¹⁹—O—R²⁰—, R²¹—S—R²² or —R²³—C(═O)—OR²⁴— (R¹⁹ to R²⁴ respectively independently are an alkylene group having 1 to 6 carbon atoms which may have a substituent group),

where in the above general formula (4), X⁷ to X¹⁰ respectively independently are a group represented by —H, —R²⁵, —OR²⁶, —O—C(═O)—R²⁷, —C(═O)—OR²⁸, or —O—C(═O)—OR²⁹ (R²⁵ to R²⁹ respectively independently are a hydrogen atom or an alkyl group having 1 to 6 carbon atoms, alkenyl group having 2 to 6 carbon atoms, cycloalkyl group having 3 to 14 carbon atoms, cycloalkenyl group having 3 to 14 carbon atoms, or aryl group having 6 to 12 carbon atoms which may have a substituent group), and

the triazine structure-containing polymer may contain two or more units having different structures as one or both of the units represented by the above general formula (3) and the units represented by the above general formula (4).],

[4]A resin shaped article obtained by causing polymerization of the polymerizable composition according to any of [1] to [3],
[5]A composite comprising the resin shaped article according to [4] and a support, and
[6]A laminate which is obtained by laminating the resin shaped article of the composite according to [5] with a metal foil.

### Effects of the Invention

According to the present invention, it is possible to provide a polymerizable composition and resin shaped article which are useful for the manufacture of a laminate which has a low dielectric tangent in the high frequency region and is excellent in peel strength, and to provide a composite and laminate which are obtained using the same.

### DESCRIPTION OF EMBODIMENTS

(Polymerizable Composition)

The polymerizable composition of the present invention comprises a cycloolefin monomer (A), metathesis polymerization catalyst (B), and polymer (C) which has a triazine structure at its side chain.

(Cycloolefin Monomer (A))

The cycloolefin monomer (A) used in the present invention is a compound which has a ring structure which is formed by carbon atoms and has carbon-carbon double bonds in the ring structure. As the cycloolefin monomer (A), for example, a norbornene-based monomer and monocyclic cycloolefin etc. may be mentioned. As the cycloolefin monomer (A), a norbornene-based monomer is preferably used. A norbornene-based monomer is a monomer which contains a norbornene ring.

The norbornene-based monomer is not particularly limited, for example, 2-norbornene, norbornadiene, or other bicyclic compound, dicyclopentadiene, dihydrodicyclopentadiene, or other tricyclic compound, tetracyclododecene, ethylidene tetracyclododecene, phenyl tetracyclododecene, or other tetracyclic compound, tricyclopentadiene or other pentacyclic compound, tetracyclopentadiene or other heptacyclic compound, and their alkyl substituted compounds (for example, methyl-, ethyl-, propyl-, and butyl-substituted compounds etc.), alkylidene-substituted compounds (for example, ethylidene-substituted compounds), aryl-substituted compounds (for example, phenyl- and tolyl-substituted compounds), and derivatives having epoxy groups, hydroxyl groups, amino groups, carboxyl groups, cyano groups, halogen groups, ether groups, ester bond-containing groups, or other polar groups etc. may be mentioned.

As the monocyclic cycloolefin, for example, cyclobutene, cyclopentene, cyclooctene, cyclododecene, 1,5-cyclooctadiene, and their derivatives having substituents may be mentioned.

These cycloolefin monomers (A) may be used alone or as two types or more combined. A resin shaped article which is obtained by polymerization of a polymerizable composition including such a cycloolefin monomer (A) and a composite and laminate which are obtained using the resin shaped article are low in dielectric tangent in the high frequency region. Therefore, these are suitable as materials with small transmission loss which can be used for high performance printed circuit boards etc.

(Metathesis Polymerization Catalyst (B))

The metathesis polymerization catalyst (B) used in the present invention is not particularly limited so long as able to make the cycloolefin monomer (A) polymerize by metathesis ring-opening polymerization. As the metathesis polymerization catalyst (B), a transition metal complex which has a transition metal atom as the center atom to which a plurality of ions, atoms, and polyatomic ions and/or compounds are bonded may be mentioned. As the transition metal atom, an atom of the Group V, Group VI, and Group VIII (according to long form Periodic Table, same below) is used. The atoms of these groups are not particularly limited, but as atoms of the Group V, for example, tantalum may be mentioned, as atoms of the Group VI, for example, molybdenum or tungsten may be mentioned, while as atoms of the Group VIII, for example, ruthenium or osmium may be mentioned. Among these as well, use of a complex which has ruthenium or osmium of Group VIII as a center atom as a metathesis polymerization catalyst is preferable, use of a complex which has ruthenium as a center atom is more preferable, and use of a ruthenium carbene complex is particularly preferable. A ruthenium carbene complex is a complex which has the structure of a ruthenium atom to which a carbene carbon is double bonded (Ru═C) and is excellent in catalytic activity at the time of polymerization. For this reason, when polymerizing a polymerizable composition which contains a metathesis polymerization catalyst (B) constituted by a ruthenium carbene complex to manufacture a resin shaped article, it is possible to reduce the ratio of content of the unreacted monomers in the obtained resin shaped article and possible to reduce the odor derived from the unreacted monomers. Further, due to this, a good quality shaped article is obtained with good productivity. Further, a ruthenium carbene complex is relatively stable against oxygen or the moisture in the air and resistant to loss of activity, so can be used even in an air atmosphere.

Here, as the ruthenium carbene complex, one which has a carbene compound which has a heterocyclic structure as a ligand is preferable. By using such a ruthenium carbene complex, it is possible to balance the mechanical strength and impact resistance of the resin shaped article which is obtained by polymerization of the polymerizable composition and the laminate which is obtained using the resin shaped article to a high degree. Note that, the “hetero atom” which forms the heterocyclic structure means an atom of the Group XV and Group XVI of the Periodic Table. For example, an oxygen atom, nitrogen atom, phosphorus atom, sulfur atom, etc. may be mentioned. Further, as the heterocyclic structure, an imidazoline ring structure or imidazolidine ring structure is preferable. As specific examples of such a heterocyclic structure, 1,3-di(1-adamantyl) imidazolidin-2-ylidene, 1,3-dimesityloctahydrobenzimidazol-2-ylidene, 1,3-di(1-phenylethyl)-4-imidazolin-2-ylidene, 1,3,4-triphenyl-2,3,4,5-tetrahydro-1H-1,2,4-triazol-5-ylidene, 1, 3-dicyclohexylhexahydropyrimidin-2-ylidene, N,N,N′,N′-tetraisopropylformamidinylidene, 1,3-dimesitylimidazolidin-2-ylidene, 1, 3-dicyclohexylimidazolidin-2-ylidene, 1,3-diisopropyl-4-imidazolin-2-ylidene, 1,3-dimesityl-2,3-dihydrobenzimidazol-2-ylidene, etc. may be mentioned.

As preferable examples of the metathesis polymerization catalyst (B), benzylidene(1,3-dimesitylimidazolidin-2-ylidene) (tricyclohexylphosphine) ruthenium dichloride, (1,3-dimesitylimidazolidin-2-ylidene) (3-methyl-2-buten-1-ylidene) (tricyclopentylphosphine) ruthenium dichloride, (1,3-dimesityl-4,5-dibromo-4-imidazolin-2-ylidene) (2-pyrrolidon-1-ylmethylene) (tricyclohexylphosphine) ruthenium dichloride, benzylidene(1, 3-dimesityl-octahydrobenzimidazol-2-ylidene) (tricyclohexylphosphine) ruthenium dichloride, benzylidene[1,3-di(1-phenylethyl)-4-imidazolin-2-ylidene](tricyclohexylphosphine) ruthenium dichloride, benzylidene (1,3-dimesityl-2,3-dihydrobenzimidazol-2-ylidene) (tricyclohexylphosphine) ruthenium dichloride, benzylidene (tricyclohexylphosphine) (1,3,4-triphenyl-2,3,4,5-tetrahydro-1H-1,2,4-triazol-5-ylidene) ruthenium dichloride, (1,3-diisopropylhexahydropyrimidin-2-ylidene) (ethoxymethylene) (tricyclohexylphosphine) ruthenium dichloride, benzylidene (1, 3-dimesitylimidazolidin-2-ylidene)pyridineruthenium dichloride, benzylidene (1, 3-dimesityl-4-imidazolidin-2-ylidene) (tricyclohexylphosphine) ruthenium dichloride, (1, 3-dimesityl-4-imidazolin-2-ylidene) (2-pyrrolidon-1-ylmethylene) (tricyclohexylphosphine) ruthenium dichloride, or other ruthenium complex compound which has a compound in which a heterocyclic structure and neutral electron-donor compound are bonded to a ruthenium atom as a ligand may be mentioned.

These metathesis polymerization catalysts (B) may be used alone or as two types or more combined. Note that, the amount of the metathesis polymerization catalyst (B) may for example be made the amount described in Japanese Patent Publication No. 2009-242568A.

Note that, the metathesis polymerization catalyst (B) may be used in a state dissolved or suspended in a small amount of inert solvent in accordance with need. As such a solvent, n-pentane, n-hexane, n-heptane, liquid paraffin, mineral spirits, or other chain aliphatic hydrocarbon; cyclopentane, cyclohexane, methylcyclohexane, dimethylcyclohexane, trimethylcyclohexane, ethylcyclohexane, diethylcyclohexane, decahydronaphthalene, dicycloheptane, tricyclodecane, hexahydroindene, cyclooctane, or other alicyclic hydrocarbon; benzene, toluene, xylene, or other aromatic hydrocarbon; indene, tetrahydronaphthalene, or other hydrocarbon which has an aliphatic ring and aromatic ring; nitromethane, nitrobenzene, acetonitrile, or other nitrogen-containing hydrocarbon; diethyl ether, tetrahydrofuran, or other oxygen-containing hydrocarbon; etc. may be mentioned.

(Polymer (C) which has Triazine Structure)

The polymer (C) which has a triazine structure used in the present invention (below, suitably called a “triazine structure-containing polymer (C)”) is a polymer which has a triazine structure. The triazine structure-containing polymer (C) preferably has the triazine structure at the side chain of the polymer. Note that, in the present invention, “has a triazine structure at the side chain” means not the state where the triazine structure forms the main chain of the polymer, but the state where the triazine structure is bonded with the main chain of the polymer directly or through another group. Further, the triazine structure-containing polymer (C) may also have a ring-shaped main chain structure. In this case as well, having a structure where a triazine structure is substantially not incorporated in the ring-shaped main chain structure is preferable. In the present invention, by mixing such a triazine structure-containing polymer (C) in the polymerizable composition, for example, when forming a composite which is provided with a polyethylene terephthalate (PET) film or other support and a resin shaped article obtained by polymerization of the polymerizable composition and laminating the resin shaped article side of this composite on metal foil, the peel strength of this metal foil and resin shaped article can be improved.

Further, the polymer (C) which has a triazine structure used in the present invention includes an oligomer with a relatively low polymerization degree (for example, oligomer with a polymerization degree of 3 or so or 3 or more).

The triazine structure-containing polymer (C) need only be a polymer which has a triazine structure. It is not particularly limited, but from the viewpoint of the effect of improvement of the peel strength, a triazine structure-containing polymer (C1) which is obtained by a condensation reaction of a compound represented by the following general formula (1A) or (1B) and a compound represented by the following general formula (2A) or (2B) is suitable.

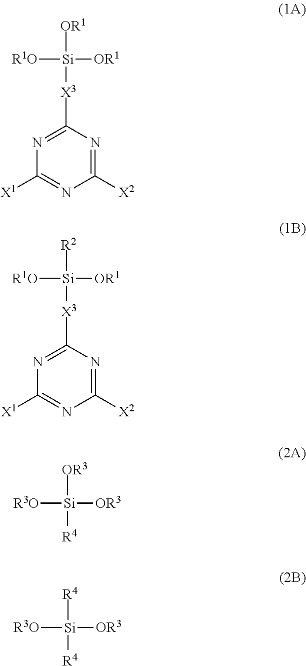

In the above general formulas (1A) and (1B), R is a hydrogen atom or an alkyl group having 1 to 6 carbon atoms, preferably an alkyl group having 1 to 4 carbon atoms. R² is an alkyl group having 1 to 6 carbon atoms, alkenyl group having 2 to 6 carbon atoms, cycloalkyl group having 3 to 14 carbon atoms, cycloalkenyl group having 3 to 14 carbon atoms or aryl group having 6 to 12 carbon atoms which may have a substituent group. Further, X¹ and X² are respectively independently a group represented by —H, —OR⁵, —SR⁶, or —NR⁷R⁸ (R⁵ to R⁸ are respectively independently a hydrogen atom, or an alkyl group having 1 to 12 carbon atoms or aryl group having 6 to 12 carbon atoms which may have a substituent group.), preferably a group represented by —NR⁷R⁸. Further, X³ is a chemical single bond or group represented by —R⁹—O—R¹⁰—, —R¹¹—S—R¹²—, or —R¹³—C(═O)—OR¹⁴— (R⁹ to R¹⁴ are respectively independently an alkylene group having 1 to 6 carbon atoms which may have a substituent group.), preferably a group represented by —R¹¹—S—R¹²—.

On the other hand, in the above general formulas (2A) and (2B), R³ is a hydrogen atom or an alkyl group having 1 to 6 carbon atoms, preferably an alkyl group having 1 to 4 carbon atoms. R⁴ is an alkyl group having 1 to 6 carbon atoms, alkenyl group having 2 to 6 carbon atoms, cycloalkyl group having 3 to 14 carbon atoms, cycloalkenyl group having 3 to 16 carbon atoms or aryl group having 6 to 14 carbon atoms which may have a substituent group. Note that, as the compound represented by the above general formulas (2A) and (2B), one where R⁴ is a cycloalkyl group having 3 to 14 carbon atoms is preferable, and one where R⁴ is cycloalkyl group having 7 to 12 carbon atoms and R⁴ includes a group which has a norbornene ring is particularly preferable. By introducing such a cycloalkenyl group, particularly a group which has a norbornene ring, it is possible to make the triazine structure-containing polymer (C1) which is obtained by a condensation reaction one which is copolymerizable with the above-mentioned cycloolefin monomer (A). Due to this, it is possible to make the polymer which is obtained by polymerization one having a three-dimensional structure. As a result, it is possible to raise the peel strength more when made into a laminate.

The triazine structure-containing polymer (C1) used in the present invention, as explained above, is a compound which is obtained by a condensation reaction of the compound represented by the above general formula (1A) or (1B) and the compound represented by the above general formula (2A) or (2B). The units based on compounds represented by the above general formula (1A) or (1B) exhibit the action of improving the peel strength due to the effect of the triazine structure. Further, the units based on compounds represented by the above general formula (2A) or (2B) have the action of improving the compatibility with the cycloolefin monomer (A). Further, according to the present invention, by using a triazine structure-containing polymer (C1) which is provided with units which have the action of improving the peel strength and units which have the action of improving the compatibility with the cycloolefin monomer (A), it is possible to suitably improve the peel strength of the obtained laminate.

Note that, on the other hand, 2,4-diaminotriazine or other general triazine compound has a high affinity with metal foil or other substrate, but does not have segments which exhibit compatibility with the cycloolefin monomer (A), so even if mixed in as it is, a sufficient effect of improvement of the peel strength could not be obtained. As opposed to this, in the present invention, by making the compound one with a triazine structure at the side chain, and by introducing units which have compatibility with the cycloolefin monomer (A) such as units based on the compound represented by the above general formula (2A) or (2B), it becomes possible to improve compatibility with the cycloolefin monomer (A) and thereby strikingly improve the peel strength when made into a laminate.

The triazine structure-containing polymer (C1) used in the present invention is not particularly limited in the method of causing the condensation reaction between the compound represented by the above general formula (1A) or (1B) and the compound represented by the above general formula (2A) or (2B), but, for example, the method of hydrolyzing the —OR¹ group of the compound represented by the above general formula (1A) or (1B) and hydrolyzing the —OR³ group of the compound represented by the above general formula (2A) or (2B) and dehydrating and condensing the obtained hydrolyzed product of the compound represented by the general formula (1A) or (1B) and the hydrolyzed product of the compound represented by the general formula (2A) or (2B) may be mentioned. At this time, the hydrolysis reaction and dehydration condensation reaction may be performed by known methods.

Further, in the present invention, as the compound represented by the above general formula (1A) or (1B), a plurality of compounds in which any of R², X¹, X², and X³ differ from each other may be used. In this case, as the units based on the compound represented by the above general formula (1A) or (1B), a plurality of units in which any of X¹, X², and X³ differ from each other may be introduced into the triazine structure-containing polymer (C1). Similarly, as the compound represented by the above general formula (2A) or (2B), a plurality of compounds in which R⁴ differs from each other may be used. In this case, as the units based on the compound represented by the above general formula (2A) or (2B), a plurality of units in which R⁴ differs from each other may be introduced into the triazine structure-containing polymer (C1).

A triazine structure-containing polymer (C1) which is obtained in this way by causing the compound represented by the above general formula (1A) or (1B) and the compound represented by the above general formula (2A) or (2B) to react by a condensation reaction, for example, may be considered one having below structural units. That is, it may be considered one which has, as units based on the compound represented by the above general formula (1A) or (1B), units represented by the following general formula (5) and has, as units based on the compound represented by the above general formula (2A) or (2B), units represented by the following general formula (6).

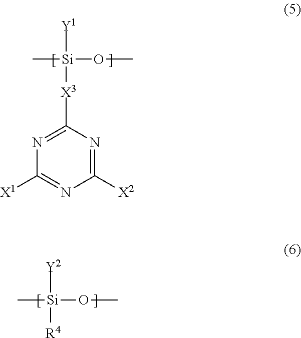

Here, in the above general formula (5), X¹ to X³ are similar to the above general formulas (1A) and (1B), and Y is a group represented by R² (R² is similar to the above general formulas (1A) and (1B).), —OH, or —OR¹ (R¹ is similar to the above general formulas (1A) and (1B).), units represented by the above general formula (5), or units represented by the above general formula (6). That is, in the units represented by the above general formula (5), at least two of the three or two —OR¹ groups which were present in the compound represented by the above general formula (1A) or (1B) participate in the condensation reaction and form condensed structures. On the other hand, as remaining one —OR¹ group, it is considered that a part of this does not participate in the condensation reaction but remains as a group represented by —OH or —OR¹, and the remaining part of this participates in the condensation reaction so as to form a condensed structure together with still other units (that is, units represented by the above general formula (5) and units represented by the above general formula (6)).

Further, in the above general formula (6), R⁴ is similar to the above general formulas (2A) and (2B), Y² is a group represented by R⁴ (R⁴ is similar to the above general formulas (2A) and (2B)), —OH, or —OR³ (R³ is similar to the above general formulas (2A) and (2B)), or units represented by the above general formula (5) or units represented by the above general formula (6). That is, in the units represented by the above general formula (6) as well, at least two of the three or two —OR³ groups which were present in the compound represented by the above general formula (2A) or (2B) participate in the condensation reaction and form condensed structures. On the other hand, as remaining one —OR³ group, it is considered that a part of this does not participate in the condensation reaction but remains as a group represented by —OH or —OR³, and the remaining part of this participates in the condensation reaction so as to form a condensed structure together with still other units (that is, units represented by the above general formula (5) and units represented by the above general formula (6)).

In the triazine structure-containing polymer (C1) used in the present invention, the ratio of the units based on the compound represented by the above general formula (1A) or (1B) and the units based on the compound represented by the above general formula (2A) or (2B) may be suitably set according to the targeted peel strength and compatibility with the cycloolefin monomer (A), but is preferably a molar ratio of the “units based on the compound represented by above general formula (1A) or (1B):units based on the compound represented by the above general formula (2A) or (2B)” of 0.1:99.9 to 20:80, more preferably 5:95 to 15:85. Note that, the ratio of the units based on the compound represented by the above general formula (1A) or (1B) and the units based on the compound represented by the above general formula (2A) or (2B) can be controlled by adjusting the ratio of the compound represented by the above general formula (1A) or (1B) and compound represented by the above general formula (2A) or (2B) which are used for the condensation reaction.

Further, in the present invention, as the triazine structure-containing polymer (C), instead of the above-mentioned triazine structure-containing polymer (C1) or together with the triazine structure-containing polymer (C1), a triazine structure-containing polymer (C2) which has units which are represented by the following general formula (3) and units which are represented by the following general formula (4) may also be used. By using the triazine structure-containing polymer (C2), in the same way as the above-mentioned triazine structure-containing polymer (C1), the effect of improvement of the peel strength becomes higher, so this is suitable.

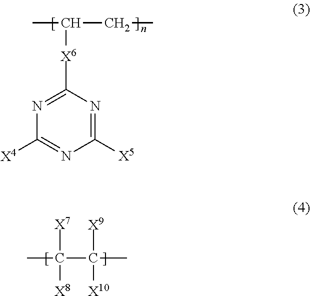

In the above general formula (3), X⁴ and X⁵ respectively independently are a group represented by —H, —OR¹⁵, —SR¹⁶, or —NR¹⁷R¹⁸ (R¹⁵ to R¹⁸ respectively independently are a hydrogen atom, or an alkyl group having 1 to 12 carbon atoms or an aryl group having 6 to 12 carbon atoms which may have a substituent group.), preferably a group represented by —NR¹⁷R¹⁸. Further, in the above general formula (3), X⁶ is a chemical single bond or group represented by —R¹⁹—O—R²⁰—, —R²¹—S—R²²—, or —R²³—C(═O)—OR²⁴— (R¹⁹ to R²⁴ respectively independently are an alkylene group having 1 to 6 carbon atoms which may have a substituent group), preferably a chemical single bond. Note that, the triazine structure-containing polymer (C2) used in the present invention may also contain, as units represented by the above general formula (3), a plurality of units where any of X⁴, X⁵, and X⁶ are different from each other.

On the other hand, in the above general formula (4), X⁷ to X¹⁰ respectively independently are groups represented by —H, —R²⁵, —OR²⁶, —O—C(═O)—R²⁷, —C(═O)—OR²⁸, or —O—C(═O)—OR²⁹ (R²⁵ to R²⁹ respectively independently are a hydrogen atom, or an alkyl group having 1 to 6 carbon atoms, an alkenyl group having 2 to 6 carbon atoms, a cycloalkyl group having 3 to 14 carbon atoms, a cycloalkenyl group having 3 to 14 carbon atoms, or an aryl group having 6 to 12 carbon atoms which may have a substituent group.). Note that, the triazine structure-containing polymer (C2) used in the present invention may also contain, as units represented by the above general formula (4), a plurality of units where any of X⁷ to X¹⁰ are different from each other.

In the units represented by the above general formula (4), when either of X⁷ to X¹⁰ is a group represented by —R²⁵, —OR²⁶, —O—C(═O)—R²⁷, —C(═O)—OR²⁸, or —O—C(═O)—OR²⁹, ones having a cycloalkenyl group having 3 to 14 carbon atoms as these R²⁵ to R²⁹ are preferable, while ones having a norbornene ring having 7 to 12 carbon atoms are particularly preferable. By introducing such a cycloalkenyl group, particularly group having norbornene ring, it is possible to make the triazine structure-containing polymer (C2) used in the present invention one which is copolymerizable with the above-mentioned cycloolefin monomer (A). Due to this, it is possible to make the polymer which is obtained by polymerization a three-dimensional one and as a result it is possible to increase the peel strength more in the case made a laminate.

The triazine structure-containing polymer (C2) used in the present invention, as explained above, is one having units represented by the above general formula (3) and units represented by the above general formula (4). The units represented by the above general formula (3) exhibit the action of improving the peel strength due to the effect of the triazine structure, further, the units represented by the above general formula (4) exhibit the action of improving the compatibility with the cycloolefin monomer (A). According to the present invention, by using a triazine structure-containing polymer (C2) provided with units which have such an action of improving the peel strength and units which have the action of improving the compatibility with the cycloolefin monomer (A), it is possible to suitably improve the peel strength of the obtained laminate.

Note that, on the other hand, 2,4-diaminotriazine or other general triazine compound is high in affinity with metal foil or other substrates, but does not have segments which exhibit compatibility with the cycloolefin monomer (A), so does not dissolve with the cycloolefin monomer (A). Therefore, even if mixing this in as it is, it was not possible to sufficiently obtain the effect of improvement of the peel strength. As opposed to this, in the present invention, by making the compound one with a triazine structure at the side chain, and for example, by introducing units which have compatibility with the cycloolefin monomer (A) such as units based on a compound represented by the above general formula (4), it becomes possible to improve the cycloolefin monomer (A) and thereby strikingly improve the peel strength in the case when made into a laminate.

In the triazine structure-containing polymer (C2) used in the present invention, the ratio of the units represented by the above general formula (3) and the units represented by the above general formula (4) may be suitably set in accordance with the target peel strength and compatibility with the cycloolefin monomer (A), but is preferably a molar ratio of the “units represented by the above general formula (3):units represented by the above general formula (4)” of 0.01:99.99 to 20:80, more preferably 2:98 to 5:95. Further, the weight average molecular weight of the triazine structure-containing polymer (C2) used in the present invention is preferably 1,000 to 100,000, more preferably 2,000 to 12,000.

The triazine structure-containing polymer (C2) used in the present invention usually can be manufactured by copolymerization of a compound represented by the following general formula (7) and a compound represented by the following general formula (8). As the type of copolymerization, either of block copolymerization or random copolymerization may be used, but from the viewpoint of the action and effect of it becoming more remarkable, block copolymerization is preferable. Note that, when including, as the units represented by the above general formula (3), a plurality of units with any of X⁴, X⁵, and X⁶ which are different from each other, it is sufficient to use a corresponding plurality of compounds as the compound represented by the following general formula (7). Similarly, when including, as the units represented by the above general formula (4), a plurality of units with any of X⁷ to X¹⁰ which are different from each other, it is sufficient to use a corresponding plurality of compounds as the compound represented by the following general formula (8).

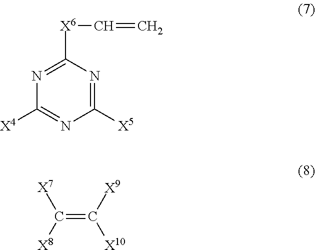

(in the above general formulas (7) and (8), X⁴ to X¹⁰ are similar to the above general formulas (3) and (4))

In the polymerizable composition of the present invention, the amount of the triazine structure-containing polymer (C) is preferably 0.1 to 20 parts by weight with respect to 100 parts by weight of the cycloolefin monomer (A), more preferably 0.2 to 10 parts by weight, furthermore preferably 0.5 to 10 parts by weight, particularly preferably 1 to 5 parts by weight. If the amount of the triazine structure-containing polymer (C) is too small, the effect of improvement of the peel strength becomes difficult to obtain, while if the amount is too great, the peel strength is liable to remarkably fall.

(Other Compounding Agents)

The polymerizable composition of the present invention may contain a radical generator, in addition to the above cycloolefin monomer (A), metathesis polymerization catalyst (B), and triazine structure-containing polymer (C). By further containing a radical generator, it is possible to cause a cross-linking reaction in the resin shaped article which is obtained by polymerization of the polymerizable composition of the present invention. Due to this, the resin shaped article can be made a post-cross-linkable shaped article. Here, the “post-cross-linkable” means the ability of the resin shaped article to be heated so as to make the cross-linking reaction progress and obtain a cross-linked resin.

As the radical generator, for example, an organic peroxide, diazo compound, nonpolar radical generator, etc. may be mentioned.

As the organic peroxide, for example, t-butyl hydroperoxide, p-mentane hydroperoxide, cumen hydroperoxide, or other hydroperoxides; dicumyl peroxide, t-butylcumyl peroxide, α,α′-bis(t-butylperoxy-m-isopropyl)benzene, di-t-butyl peroxide, 2,5-dimethyl-2,5-di(t-butylperoxy)-3-hexine, 2,5-dimethyl-2,5-di(t-butylperoxy)hexane, or other dialkyl peroxides; dipropionyl peroxide, benzoyl peroxide, or other diacyl peroxides; 2,2-di(t-butylperoxy) butane, 1,1-di(t-hexylperoxy)cyclohexane, 1,1-di(t-butylperoxy)-2-methylcyclohexane, 1,1-di(t-butylperoxy)cyclohexane, or other peroxy ketals; t-butylperoxy acetate, t-butylperoxy benzoate, or other peroxy esters; t-butylperoxyisopropyl carbonate, di(isopropylperoxy)dicarbonate, or other peroxy carbonates; t-butyltrimethylsilyl peroxide, or other alkylsilyl peroxides; 3,3,5,7,7-pentamethyl-1,2,4-trioxepane, 3,6,9-triethyl-3,6,9-trimethyl-1,4,7-triperoxonane, 3,6-diethyl-3,6-dimethyl-1,2,4,5-tetroxane, or other cyclic perioxides; may be mentioned.

As the diazo compound, for example, 1,1′-azobis(cyclohexane-1-carbonitrile), 4,4′-bisazidobenzal (4-methyl)cyclohexanone, 2,6-bis(4′-azidobenzal)cyclohexanone, etc. may be mentioned.

As the nonpolar radical generators, 2,3-dimethyl-2,3-diphenylbutane, 3,4-dimethyl-3,4-diphenylhexane, 1,1,2-triphenylethane, 1,1,1-triphenyl-2-phenylethane, etc. may be mentioned.

These radical generators can be used respectively independently or as two types or more combined. Note that, the one-minute half life temperature and amount of the radical generator can, for example, be made the ranges described in Japanese Patent Publication No. 2009-242568A. Here, the “one-minute half life temperature” is the temperature at which half of the amount of the radical generator breaks down in one minute.

Further, when mixing in a radical generator, a cross-linking aid may further be mixed in. As the cross-linking aid, there is a polyfunctional compound which has two or more functional groups which do not participate in the ring-opening polymerization reaction, but can participate in the cross-linking reaction which is caused by the cross-linking agent and can form part of a cross-linked structure.

As the functional group of the cross-linking aid, a vinylidene group may be mentioned. In particular, due to its excellent cross-linking reactivity, a vinylidene group preferably presents as a form of an isopropenyl group or methacryloyl group, and more preferably presents as a form of a methacryloyl group.

As specific examples of the cross-linking aid, p-diisopropenyl benzene, m-diisopropenyl benzene, o-diisopropenyl benzene, or other compounds having two or more isopropenyl groups; ethylene dimethacrylate, 1,3-butylene dimethacrylate, 1,4-butylene dimethacrylate, 1,6-hexanediol dimethacrylate, polyethyleneglycol dimethacrylate, polyethyleneglycol dimethacrylate, ethyleneglycol dimethacrylate, triethyleneglycol dimethacrylate, diethyleneglycol dimethacrylate, 2,2′-bis(4-methacryloxydiethoxyphenyl)propane, trimethylolpropane trimethacrylate, pentaerythritol trimethacrylate, or other compounds having two or more methacryloyl groups (however, excluding ones corresponding to acid anhydrides having two or more carbon-carbon double bonds and acid anhydride groups explained later); etc. may be mentioned. Among these as well, as the cross-linking aid, trimethylolpropane trimethacrylate, pentaerythritol trimethacrylate, or other compounds having three methacryloyl groups are preferable, while trimethylolpropane trimethacrylate is more preferable. The cross-linking aid may be used as single type alone or as two types or more combined. The content of the cross-linking aid is preferably 0.1 to 100 parts by weight with respect to 100 parts by weight of the cycloolefin monomer, more preferably 0.5 to 50 parts by weight. By making the content of the cross-linking aid in the above range, a laminate which is excellent in heat resistance and low in dielectric tangent can be easily obtained.

The polymerizable composition of the present invention may contain, in addition to the above ingredients, as desired, a chain transfer agent, polymerization adjusting agent, polymerization reaction retarding agent, reactive fluidizing agent, filler, flame retardant, antiaging agent, coloring agent, or other compounding agents in any amount. Note that, as the chain transfer agent, polymerization adjusting agent, polymerization reaction retarding agent, reactive fluidizing agent, filler, flame retardant, antiaging agent, and coloring agent, ones constituted by generally used compounds, for example, the compounds described in Japanese Patent Publication No. 2009-242568A, the compounds described in Japanese Patent Publication No. 2010-100683A, etc. can be used.

The polymerizable composition of the present invention can be obtained by mixing the above ingredients. As the mixing method, an ordinary method may be followed. For example, it may be prepared by adding a solution obtained by making the metathesis polymerization catalyst dissolve or disperse in a suitable solvent (catalyst solution) to a solution obtained by mixing the cycloolefin monomer (A), triazine structure-containing polymer (C), or other essential ingredients and any other compounding agents (monomer solution) and stirring it.

(Resin Shaped Article)

The resin shaped article of the present invention is obtained by causing the above-mentioned polymerizable composition of the present invention to polymerize (for example, by bulk polymerization). The resin shaped article of the present invention can be laminated with another member (metal foil etc.) in accordance with need so as to produce a laminate with a metal foil etc. The composite of the present invention is provided with the resin shaped article and a support.

Here, as methods for causing a polymerizable composition to polymerize by bulk polymerization to obtain a resin shaped article, for example,

(a) the method of coating the polymerizable composition on a support, then causing it to polymerize by bulk polymerization,
(b) the method of injecting the polymerizable composition into a mold, then causing it to polymerize by bulk polymerization,
(c) the method of impregnating the polymerizable composition in a fibrous reinforcing material, then causing it to polymerize by bulk polymerization, etc.
may be mentioned. Note that, the thickness and shape of the resin shaped article can be suitably selected in accordance with the application of the resin shaped article.

According to the method of the above (a), a film-shaped or sheet-shaped resin shaped article is obtained.

Here, as the support, for example, a film or sheet comprised of polytetrafluoroethylene, polyethylene terephthalate, polypropylene, polyethylene, polycarbonate, polyethylene naphthalate, polyarylate, nylon, or other resin; a metal foil or metal sheet comprised of iron, stainless steel, copper, aluminum, nickel, chrome, gold, silver, or other metal material; etc. may be mentioned. Among these as well, as the support, a metal foil or resin film is preferable.

Note that, the thickness or surface roughness of the support can be suitably selected in accordance with the application of the resin shaped article. Further, when using a support constituted by the metal foil, metal foil treated on its surface with a silane coupling agent, thiol coupling agent, titanate coupling agent, or other known coupling agent or adhesive agent etc. may be used. Further, according to the method of the above (a), for example, when using a support constituted by the copper foil, it is possible to obtain resin coated copper foil (RCC foil).

As the method of coating the polymerizable composition of the present invention on the support, a spray coat method, dip coat method, roll coat method, curtain coat method, die coat method, slit coat method, or other known coating method may be mentioned.

Further, in the method of the above (a), the bulk polymerization is performed by making the polymerizable composition which is coated on the support dry as desired, then heating the polymerizable composition at a predetermined temperature. The method of heating the polymerizable composition is not particularly limited. The method of placing the polymerizable composition which is coated on the support on a hot plate to heat it, the method of using a press machine to press the composition while heating it (hot press), the method of pressing the composition by heated rollers, the method of heating the composition in a heating oven, etc. may be mentioned.

According to the method of the above (b), a resin shaped article of any shape can be obtained. As the shape, a sheet shape, film shape, columnar shape, cylindrical shape, polygonal cylindrical shape, etc. may be mentioned.

Here, as the mold, any known mold can be used. Further, in the method of the above (b), the polymerizable composition is injected into a cavity of a mold which has a cavity matching the shape of the shaped article and heat to cause bulk polymerization. Alternatively, in the method of the above (b), glass sheets, metal sheets or other sheet shaped molds and spacers of predetermined thicknesses are prepared and the polymerizable composition is injected into a cavity which is formed by sandwiching the spacers between two sheet shaped molds and heated to cause bulk polymerization.

Note that, the shape, material, size, etc. of the mold is not particularly limited. Further, the filling pressure (injection pressure) when filling the polymerizable composition in the mold can be made the usually used pressure. As the method of heating the polymerizable composition, the method of utilizing an electric heater which is laid in the mold, steam or other heating means, the method of heating the mold in an electric oven, etc. may be mentioned.

According to the method of the above (c), a sheet shaped or film shaped resin shaped article which contains a fibrous reinforcing material inside it is obtained.

Here, in the method of the above (c), the polymerizable composition can be impregnated in the fibrous reinforcing material by, for example, the method of coating a predetermined amount of the polymerizable composition on the fibrous reinforcing material by the spray coat method, dip coat method, roll coat method, curtain coat method, die coat method, slit coat method, or other known method, laying a protective film on it as desired, and pressing the top side by rollers etc. Further, in the method of the above (c), the polymerizable composition is impregnated in the fibrous reinforcing material, then the impregnated material is heated to cause bulk polymerization of the polymerizable composition.

Note that, as the fibrous reinforcing material, a woven fabric or nonwoven fabric of an inorganic and/or organic fiber can be used. As the organic fiber, for example, PET (polyethylene terephthalate) fiber, aramide fiber, superhigh molecular weight polyethylene fiber, polyamide (nylon) fiber, liquid crystal polyester fiber, etc. may be mentioned. Further, as the inorganic fiber, glass fiber, carbon fiber, alumina fiber, tungsten fiber, molybdenum fiber, titanium fiber, steel fiber, boron fiber, silicon carbide fiber, silica fiber, etc. may be mentioned.

As the heating method of the impregnated material comprised of the fibrous reinforcing material in which the polymerizable composition is impregnated, for example, (i) the method of setting the impregnated material on a support and heating it such as by the method of the above (a), or (ii) the method of setting the fibrous reinforcing material in a mold in advance, impregnating a polymerizable composition in the fibrous reinforcing material in the mold to obtain an impregnated material, then heating it such as by the method of the above (b) etc. may be mentioned.

Note that, in the method of each of the above (a), (b), and (c), the heating temperature for making the polymerizable composition copolymerize is usually 30 to 250° C., preferably 50 to 200° C., more preferably 90 to 150° C. Further, when the polymerizable composition contains a radical generator, the temperature may be made the one-minute half life temperature of the radical generator or less, preferably a temperature lower than the one-minute half life temperature by 10° C. or more, more preferably a temperature lower than the one-minute half life temperature by 20° C. or more. The polymerization time may be suitably selected.

(Laminate)

The laminate of the present invention is comprised of the above-mentioned resin shaped article of the present invention and a metal foil or board laminated together. Further, the laminate of the present invention is comprised of the above-mentioned composite of the present invention laminated on a metal foil or board at the resin shaped article of the resin shaped article. The laminate of the present invention can be used for manufacture of a printed circuit board or multilayer printed circuit board etc. Note that, when using a metal foil constituted by copper foil, the laminate becomes a copper-clad laminate (CCL).

Here, as the method of obtaining the laminate of the present invention, the method of using a metal foil as a support in the method of the above (a) or the method of the above (c) in which the heating method of the above (i) is employed may be mentioned. The polymerizable composition of the present invention, as explained above, contains a triazine structure-containing polymer (C) which has the action of improving the peel strength, so when obtaining the laminate of the present invention, it is sufficient to employ a method of bringing the polymerizable composition into contact with the support, without providing primer layers on the surfaces of the support or applying other special treatment, and then heating this such as the method of the above (a) or the method of the above (c) in which the heating method of the above (i) is employed. Even when employing such a method, excellent peel strength can be obtained. That is, according to the present invention, specific treatment of the surfaces of the support such as providing primer layers is not necessary, so compared with the method of forming such primer layers (for example, the method of the above-mentioned Japanese Patent No. 3862009 (Patent Document 1)), the manufacturing process can be streamlined while excellent peel strength can be realized.

Further, when mixing a radical generator in the polymerizable composition of the present invention, the resin shaped article may be cross-linked. Such cross-linking usually can be performed by heating the resin shaped article to a predetermined temperature or more. The heating temperature is usually at least the temperature at which a cross-linking reaction is caused by a radical generator. Specifically, the heating temperature is usually at least the one-minute half life temperature of a radical generator, preferably a temperature higher than the one-minute half life temperature by 5° C. or more, more preferably a temperature higher than the one-minute half life temperature by 10° C. or more, typically 100 to 300° C., preferably 150 to 250° C. Note that, for the heating method, hot pressing using a press machine or press forming machine or other known method can be used. Further, the heating time and the press pressure can be suitably set.

The laminate of the present invention is obtained using a resin shaped article which is obtained by polymerization of the above-mentioned polymerizable composition of the present invention, so is low in dielectric tangent in the high frequency region and is excellent in peel strength. For this reason, the laminate of the present invention can be preferably used for applications of communications devices or for microwave or milliwave or other high frequency circuit boards making use of such characteristics.

### EXAMPLES

Below, examples and comparative examples will be given to explain the present invention more specifically. In the examples, the “parts” are based on weight unless otherwise indicated. Note that, the methods of evaluation of the characteristics were as follows.

(1) Relative Permittivity and Dielectric Tangent

From the film-shaped cured article, a width 2.0 mm, length 80 mm, thickness 40 μm piece was cut out. A cavity resonator perturbation method permittivity measurement apparatus (made by Agilent Technology) was used to measure the relative permittivity and dielectric tangent (tan δ) at 20° C. and a frequency of 10 GHz. There were evaluated by the following indicators.

A: Relative permittivity of less than 2.40

C: Relative permittivity of 2.70 or more

A: Dielectric tangent of less than 0.005

C: Dielectric tangent of 0.010 or more

(2) Peel Strength

The strength when peeling off the copper foil from the prepared copper-clad laminate (laminate) was measured based on JIS C6481.

### Manufacturing Example 1

The diaminotriazine structure-containing silane compound represented by the above formula (9) 3.47 parts and the norbornene structure-containing silane compound represented by the following formula (10) 21.2 parts were used. By the methods of hydrolysis of alkoxysilane and a dehydration condensation reaction, these were hydrolyzed and the obtained hydrolyzed product was treated by dehydration condensation to obtain a diaminotriazine structure-containing silane compound/norbornene structure-containing silane compound condensate. The obtained copolymer was measured by elementary analysis for ratio of composition, whereby the units based on the diaminotriazine structure-containing silane compound were 10 mol % and the units based on the norbornene structure-cotnaining silane compound were 90 mol %. Further, the weight average molecular weight was 942.

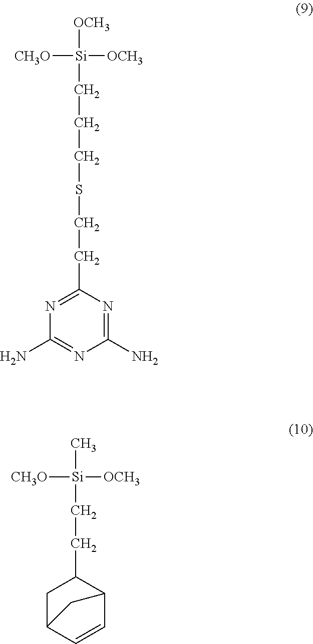

### Manufacturing Example 2

The diaminotriazine structure-containing silane compound represented by the above formula (9) 3.47 parts and the dimethyl dimethoxysilane represented by the following formula (11) 11.3 parts were used. By hydrolysis of alkoxysilane and a dehydration condensation reaction, these were hydrolyzed and the obtained hydrolyzed product was treated by dehydration condensation to obtain a diaminotriazine structure-containing silane compound/dimethyl dimethoxysilane condensate. The obtained copolymer was measured by elementary analysis for ratio of composition, whereby the units based on the diaminotriazine structure-containing silane compound were 10 mol % and the units based on the dimethyl dimethoxysilane were 90 mol %. Further, weight average molecular weight was 1,143.

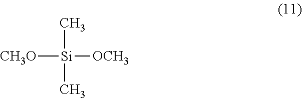

### Manufacturing Example 3

2-vinyl-4,6-diamino-1,3,5-triazine 10.7 parts, 5-norbornen-2-yl methacrylate 150 parts, and styrene 312 parts were copolymerized by radical polymerization using 1,1′-azobis(cyclohexane-1-carbonitrile) as a radical initiator to obtain a 2-vinyl-4,6-diamino-1,3,5-triazine/5-norbornen-2-yl methacrylate/styrene copolymer which is shown by the following formula (12). Note that, the obtained copolymer was measured by elementary analysis and FT-IR analysis for ratio of composition, whereby in the following formula (12), the molar ratio of the units which are represented by “a” was 2 mol %, the molar ratio of the units which are represented by “b” was 21 mol %, and the molar ratio of the units which are represented by “c” was 77 mol %. Further, the weight average molecular weight was 7522.

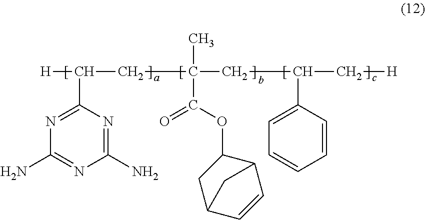

### Manufacturing Example 4

2-vinyl-4,6-diamino-1,3,5-triazine 2.36 parts and 5-norbornen-2-yl methacrylate 150 parts were copolymerized by radical polymerization using 1,1′-azobis(cyclohexane-1-carbonitrile) as a radical initiator to obtain a 2-vinyl-4, 6-diamino-1,3,5-triazine/5-norbornen-2-yl methacrylate copolymer which is shown by the following formula (13). Note that, the obtained copolymer was measured by elementary analysis for ratio of composition, whereby in the following formula (13), the molar ratio of the units which are represented by “d” was 2 mol % and the molar ratio of the units which are represented by “e” was 98 mol %. Further, the weight average molecular weight was 9113.

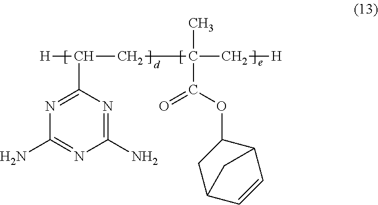

### Manufacturing Example 5

2-vinyl-4,6-diamino-1,3,5-triazine 15.0 parts and styrene 559 parts were copolymerized by radical polymerization using 1,1′-azobis(cyclohexane-1-carbonitrile) as a radical initiator to obtain a 2-vinyl-4,6-diamino-1,3,5-triazine/styrene copolymer which is shown by the following formula (14). Note that, the obtained copolymer was measured by elementary analysis for ratio of composition, whereby in the following formula (14), the molar ratio of the units which are represented by “f” was 2 mol % and the molar ratio of the units which are represented by “g” was 98 mol %. Further, the weight average molecular weight was 9578.

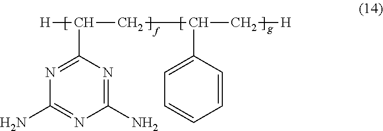

### Example 1

A metathesis polymerization catalyst constituted by (1,3-dimesityl-4-imidazolin-2-ylidene)(2-pyrrolidon-1-ylmethylene)(tricyclohexylphosphine) ruthenium dichloride (synthesized by method described in International Publication No. 2009/123209A) 51 parts and triphenylphosphine 79 parts were made to dissolve in toluene 952 parts to prepare a catalyst solution.

Further, separate from this, a cycloolefin monomer constituted by ethylidenetetracyclo[6.2.1.1^{3,6}.0^{2,7}]dodec-4-ene (ETD) 100 parts, a triazine structure-containing condensate constituted by the diaminotriazine structure-containing silane compound/norbornene structure-containing silane compound condensate which was obtained in the above Manufacturing Example 1, 2 parts, and silica microparticles (Product name “RX50”, made by Nippon Aerosil, 1,1,1,3,3,3-hexamethylene disilazane treated product, average particle size: 40 nm) 50 parts were mixed to prepare a monomer solution.

Further, to the obtained monomer solution, the above prepared catalyst solution was added and stirred in a ratio giving an amount of the metathesis polymerization catalyst of 0.0627 part with respect to 100 parts of the cycloolefin monomer to prepare a polymerizable composition.

Next, the obtained polymerizable composition was directly coated on copper foil which was microetched using a surface roughening agent (CZ-8100, made by MEC Company) (surface-roughened copper foil, thickness: 30 μm, surface roughness Ra=500 nm). This was heated at 120° C. for 10 minutes to thereby cause bulk polymerization of the polymerizable composition to obtain a composite comprised of copper foil and a resin shaped article. Further, the obtained composite was bonded, at the resin shaped article side of the composite, to a product in which a buildup film (made by Ajinomoto) was bonded to a board at the film side by lamination and heat treated in a nitrogen atmosphere at 195° C. for 30 minutes to obtain a copper-clad laminate (laminate). As the board, thickness 0.8 mm double-side copper-clad board obtained by cladding thickness 18 μm copper on both surfaces of a core material obtained by impregnating a varnish containing a glass filler and halogen-free epoxy compound in glass fiber, and microetching its surfaces by a surface roughening agent (CZ-8100) (surface roughness Ra=500 nm) was used. Further, the obtained copper-clad laminate was used to measure it for peel strength by the above method.

On the other hand, the above composite was stripped of the copper foil by etching, then dried to obtain a film-shaped cured article. The obtained film-shaped cured article was used to measure it for relative permittivity and dielectric tangent by the above methods. The results are shown in Table 1.

### Example 2

Except for changing the amount of the diaminotriazine structure-containing silane compound/norbornene structure-containing silane compound condensate which was obtained at the above Manufacturing Example 1 from 2 parts to 0.2 part, the same procedure was followed as in Example 1 to obtain a polymerizable composition and copper-clad laminate (laminate) and the same procedure was followed to evaluate them. The results are shown in Table 1.

### Example 3

Except for changing the amount of the diaminotriazine structure-containing silane compound/norbornene structure-containing silane compound condensate which was obtained at the above Manufacturing Example 1 from 2 parts to 10 parts, the same procedure was followed as in Example 1 to obtain a polymerizable composition and copper-clad laminate (laminate) and the same procedure was followed to evaluate them. The results are shown in Table 1.

### Example 4

Except for using, instead of 2 parts of the diaminotriazine structure-containing silane compound/norbornene structure-containing silane compound condensate which was obtained at the above Manufacturing Example 1, 2 parts of the diaminotriazine structure-containing silane compound/dimethyl dimethoxysilane condensate which was obtained at the above Manufacturing Example 2, the same procedure was followed as in Example 1 to obtain a polymerizable composition and copper-clad laminate (laminate) and the same procedure was followed to evaluate them. The results are shown in Table 1.

### Comparative Example 1

Except for not using the diaminotriazine structure-containing silane compound/norbornene structure-containing silane compound condensate which was obtained at the above Manufacturing Example 1, the same procedure was followed as in Example 1 to obtain a polymerizable composition and copper-clad laminate (laminate) and the same procedure was followed to evaluate them. The results are shown in Table 1.

TABLE 1

| | | | | |
|---|---|---|---|---|
| | | | | Comparative |
| Example 1 | Example 2 | Example 3 | Example 4 | Example 1 |

Polymerizable composition

| | | | | | | |
|---|---|---|---|---|---|---|
| Cycloolefin monomer | (parts) | 100 | 100 | 100 | 100 | 100 |
| Diaminotriazine structure-containing | (parts) | 2 | 0.2 | 10 | — | — |
| silane compound/ | | | | | | |
| norbornene structure-containing | | | | | | |
| silane compound condensate | | | | | | |
| Diaminotriazine structure-containing | (parts) | — | — | — | 2 | — |
| silane compound/ | | | | | | |
| dimethyldimethoxy silane condensate | | | | | | |
| Silica fine particles | (parts) | 50 | 50 | 50 | 50 | 50 |
| Metathesis polymerization catalyst | (parts) | 0.0627 | 0.0627 | 0.0627 | 0.0627 | 0.0627 |

Evaluation

| | | | | | | |
|---|---|---|---|---|---|---|
| Relative permittivity | | A | A | A | A | A |
| Dielectric tangent | | A | A | A | A | A |
| Peel strength | (N/cm) | 12.3 | 11.5 | 10.2 | 10.8 | 3.8 |

The results of Examples 1 to 4 and Comparative Example 1 are shown in Table 1.

As shown in Table 1, copper-clad laminates (laminates) which were obtained by using a polymerizable composition comprised of a mixture of a cycloolefin monomer (A), metathesis polymerization catalyst (B), and triazine structure-containing polymer (C) constituted by a triazine structure-containing polymer (C1) which is obtained by causing a condensation reaction between the compound represented by the above general formula (1) and the compound represented by the above general formula (2) were low in relative permittivity and dielectric tangent and further were excellent in peel strength (Examples 1 to 4).

On the other hand, when not mixing in a triazine structure-containing polymer (C) constituted by a triazine structure-containing condensate obtained by causing a condensation reaction between the compound represented by the above general formula (1) and the compound represented by the above general formula (2), the obtained copper-clad laminate (laminate) was inferior in peel strength (Comparative Example 1).

Further, in Examples 1 and 4 and Comparative Example 1, when using, instead of microetched copper foil (surface-roughened copper foil), electrolytic copper foil not treated to roughen its surface (Type FO, product not treated by silane coupling agent, thickness 0.012 mm, made by Furukawa Electric) to obtain copper-clad laminates (laminates) and measuring them for peel strength, the peel strengths were respectively, in Example 1, 5.8N/cm, in Example 4, 5.3N/cm, and, in Comparative Example 1, 0.6N/cm. That is, from these results, it can be said that according to the present invention, it is possible to realize excellent peel strength without regard as to roughening of the surface of the copper foil.

### Example 5

Except for using as the triazine structure-containing polymer, instead of 2 parts of the diaminotriazine structure-containing silane compound/norbornene structure-containing silane compound condensate which was obtained in the above Manufacturing Example 1, 10 parts of the 2-vinyl-4,6-diamino-1,3,5-triazine/methacrylic acid 5-norbornen-2-yl/styrene copolymer which was obtained in the above Manufacturing Example 3, the same procedure was followed as in Example 1 to obtain a polymerizable composition and copper-clad laminate (laminate) and the same procedure was followed to evaluate them. The results are shown in Table 2.

### Example 6

Except for changing the amount of the 2-vinyl-4,6-diamino-1,3,5-triazine/methacrylic acid 5-norbornen-2-yl/styrene copolymer which was obtained in the above Manufacturing Example 3 from 10 parts to 1 part, the same procedure was followed as in Example 5 to obtain a polymerizable composition and copper-clad laminate (laminate) and the same procedure was followed to evaluate them. The results are shown in Table 2.

### Example 7

Except for using, instead of 10 parts of the 2-vinyl-4,6-diamino-1,3,5-triazine/methacrylic acid 5-norbornen-2-yl/styrene copolymer which was obtained in the above Manufacturing Example 3, 10 parts of the 2-vinyl-4,6-diamino-1,3,5-triazine/5-norbornen-2-yl methacrylate copolymer which was obtained in the above Manufacturing Example 4, the same procedure was followed as in Example 5 to obtain a polymerizable composition and copper-clad laminate (laminate) and the same procedure was followed to evaluate them. The results are shown in Table 2.

### Example 8

Except for using, instead of 10 parts of the 2-vinyl-4,6-diamino-1,3,5-triazine/5-norbornen-2-yl methacrylate/styrene copolymer which was obtained in the above Manufacturing Example 3, 10 parts of the 2-vinyl-4,6-diamino-1,3,5-triazine/styrene copolymer which was obtained in the above Manufacturing Example 5, the same procedure was followed as in Example 5 to obtain a polymerizable composition and copper-clad laminate (laminate) and the same procedure was followed to evaluate them. The results are shown in Table 2.

### Comparative Example 2

Except for not using the 2-vinyl-4,6-diamino-1,3,5-triazine/5-norbornen-2-yl methacrylate/styrene copolymer which was obtained in the above Manufacturing Example 3, the same procedure was followed as in Example 5 to obtain a polymerizable composition and copper-clad laminate (laminate) and the same procedure was followed to evaluate them. The results are shown in Table 2. Note that, this Comparative Example 2, in the same way as the above-mentioned Comparative Example 1, corresponds to an experiment obtaining a polymerizable composition and copper-clad laminate (laminate).

TABLE 2

| | | | | |
|---|---|---|---|---|
| | | | | Comparative |
| Example 5 | Example 6 | Example 7 | Example 8 | Example 2 |

Polymerizable composition

| | | | | | | |
|---|---|---|---|---|---|---|
| Cycloolefin monomer | (parts) | 100 | 100 | 100 | 100 | 100 |
| 2-vinyl-4,6-diamino-1,3,5-triazine/ | (parts) | 10 | 1 | — | — | — |
| 5-norbornen-2-yl methacrylate/ | | | | | | |
| styrene copolymer | | | | | | |
| 2-vinyl-4,6-diamino-1,3,5-triazine/ | (parts) | — | — | 10 | — | — |
| 5-norbornen-2-yl methacrylate copolymer | | | | | | |
| 2-vinyl-4,6-diamino-1,3,5-triazine/ | (parts) | — | — | — | 10 | — |
| styrene copolymer | | | | | | |
| Silica fine particles | (parts) | 50 | 50 | 50 | 50 | 50 |
| Metathesis polymerization catalyst | (parts) | 0.0627 | 0.0627 | 0.0627 | 0.0627 | 0.0627 |

Evaluation

| Relative permittivity | | A | A | A | A | A |
|---|---|---|---|---|---|---|
| Dielectric tangent | | A | A | A | A | A |
| Peel strength | (N/cm) | 9.5 | 11.7 | 11.1 | 8.1 | 3.8 |

The results of Examples 5 to 8 and Comparative Example 2 are shown in Table 2.

As shown in Table 2, the copper-clad laminates (laminates) which were obtained by using a polymerizable composition comprised of a cycloolefin monomer (A), metathesis polymerization catalyst (B), and triazine structure-containing polymer (C) constituted by a triazine structure-containing compound having units represented by the above general formula (3) and units represented by the above general formula (4) were low in relative permittivity and dielectric tangent and further were excellent in peel strength (Examples 5 to 8).

On the other hand, when not mixing in a triazine structure-containing polymer (C) constituted by a triazine structure-containing compound which has units represented by the above general formula (3) and units represented by the above general formula (4), the obtained copper-clad laminate (laminate) was inferior in peel strength (Comparative Example 2).

1. A polymerizable composition comprising a cycloolefin monomer (A), a metathesis polymerization catalyst (B), and a polymer (C) which has a triazine structure.

2. The polymerizable composition according to claim 1, wherein the polymer (C) which has a triazine structure is a triazine structure-containing polymer (C1) which is obtained by causing a compound represented by the following general formula (1A) or (1B) and a compound represented by the following general formula (2A) or (2B) to react by a condensation reaction. 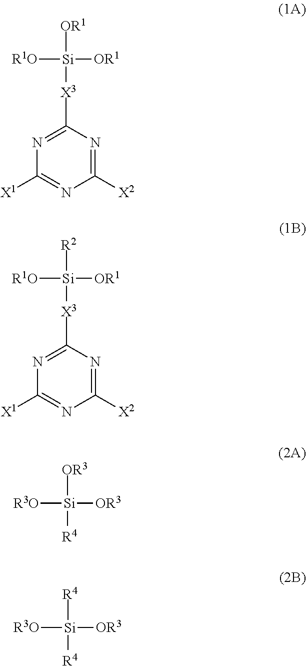
[where in the above general formulas (1A) and (1B), R¹ is a hydrogen atom or an alkyl group having 1 to 6 carbon atoms, R² is an alkyl group having 1 to 6 carbon atoms, alkenyl group having 2 to 6 carbon atoms, cycloalkyl group having 3 to 14 carbon atoms, cycloalkenyl group having 3 to 14 carbon atoms or aryl group having 6 to 12 carbon atoms which may have a substituent group, X¹ and X² respectively independently are a group represented by —H, —OR⁵, —SR⁶, or —NR⁷R⁸ (R⁵ to R⁸ respectively independently are a hydrogen atom, or an alkyl group having 1 to 12 carbon atoms or aryl group having 6 to 12 carbon atoms which may have a substituent group.), X³ is a chemical single bond or group represented by —R⁹—O—R¹⁰—, —R¹¹—S—R¹²—, or —R¹³—C(═O)—OR¹⁴— (R⁹ to R¹⁴ respectively independently are an alkylene group having 1 to 6 carbon atoms which may have a substituent group.),
where in the above general formulas (2A) and (2B), R³ is a hydrogen atom or alkyl group having 1 to 6 carbon atoms, R⁴ is an alkyl group having 1 to 6 carbon atoms, alkenyl group having 2 to 6 carbon atoms, cycloalkyl group having 3 to 14 carbon atoms, cycloalkenyl group having 3 to 14 carbon atoms or aryl group having 6 to 12 carbon atoms which may have a substituent group, and
the triazine structure-containing polymer may be obtained by a condensation reaction using two or more compounds having different structures as one or both of the compound represented by the above general formula (1A) or (1B) and the compound represented by the above general formula (2A) or (2B).]

3. The polymerizable composition according to claim 1, wherein the polymer (C) which has a triazine structure is a triazine structure-containing polymer (C2) which has units represented by the following general formula (3) and units represented by the following general formula (4). 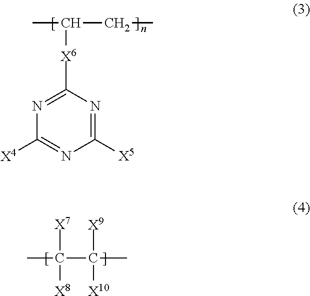
[where in the above general formula (3), X⁴ and X⁵ respectively independently are a group represented by —H, —OR¹⁵, —SR¹⁶, or —NR¹⁷R¹⁸ (R¹⁵ to R¹⁸ respectively independently are a hydrogen atom or an alkyl group having 1 to 12 carbon atoms or aryl group having 6 to 12 carbon atoms which may have a substituent group), X⁶ is a chemical single bond or group represented by —R¹⁹—O—R²⁰—, —R²¹—S—R²²—, or —R²³—C(═O)—OR²⁴— (R¹⁹ to R²⁴ respectively independently are an alkylene group having 1 to 6 carbon atoms which may have a substituent group),
where in the above general formula (4), X⁷ to X¹⁰ respectively independently are a group represented by —H, —R²⁵, —OR²⁶, —O—C(═O)—R²⁷, —C(═O)—OR²⁸, or —O—C(═O)—OR²⁹ (R²⁵ to R²⁹ respectively independently are a hydrogen atom or an alkyl group having 1 to 6 carbon atoms, alkenyl group having 2 to 6 carbon atoms, cycloalkyl group having 3 to 14 carbon atoms, cycloalkenyl group having 3 to 14 carbon atoms, or aryl group having 6 to 12 carbon atoms which may have a substituent group), and
the triazine structure-containing polymer may contain two or more units having different structures as one or both of the units represented by the above general formula (3) and the units represented by the above general formula (4).]

4. A resin shaped article obtained by causing polymerization of the polymerizable composition according to claim 1.

5. A composite comprising the resin shaped article according to claim 4 and a support.

6. A laminate obtained by laminating the resin shaped article of the composite according to claim 5 with a metal foil.
